(19) United States
(12) Patent Application Publication
(10) Pub. No.: US 2008/0113603 A1
(43) Pub. Date: May 15, 2008

(54) Computer system cooling system

(76) Inventor: Jean G. Atallah, Fremont, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/584,417

(22) Filed: Oct. 19, 2006

(51) Int. Cl. H05K 5/00

(52) U.S. Cl. 454/184

(57) ABSTRACT

A computer system cooling system, comprising a chassis comprising a first air circulation device and a second circulation device and a motherboard disposed therein, the motherboard oriented to position a card coupled thereto such that the first air circulation device is disposed on one side of the card and the second air circulation device is disposed on the opposite side of the card.

### BACKGROUND OF THE INVENTION

Computer systems comprise components that generate substantial levels of thermal energy (e.g., graphic cards, processors, etc.). If such computer systems are not sufficiently cooled, damage to and/or a reduced operating life of the computer system can result. Fans and heat exchangers (sometimes in combination with heat pipes) disposed within the computer system have been used to dissipate thermal energy from within the computer system. However, because of the placement of various components within the computer system, as well as the placement of the heat dissipating components within the computer system, airflow “dead spots” occur, resulting in a lack of a uniform, distributed airflow through the computing system and inefficient dissipation of thermal energy.

### BRIEF DESCRIPTION OF THE DRAWINGS

For a more complete understanding of the present invention, and the objects and advantages thereof, reference is now made to the following descriptions taken in connection with the accompanying drawings in which:

FIG. 1 is a diagram illustrating a computer system in which an embodiment of a cooling system is employed to advantage;

FIG. 2 is a side view of the cooling system of FIG. 1 illustrating airflow paths through the computer system illustrated in FIG. 1; and

FIG. 3 is a diagram illustrating a side view of another embodiment of a computer system cooling system.

### DETAILED DESCRIPTION OF THE DRAWINGS

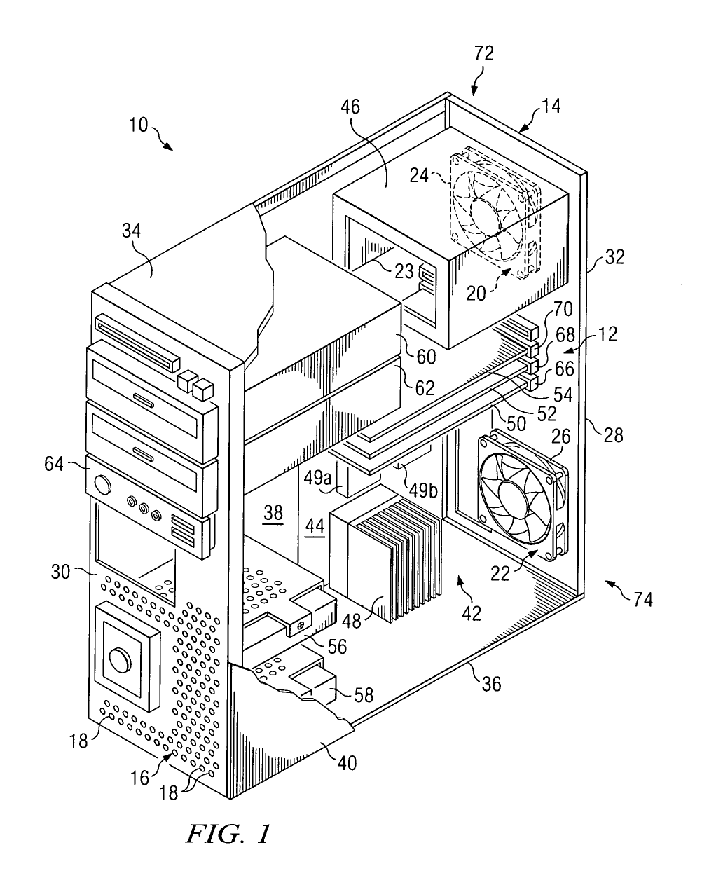

The preferred embodiments of the present invention and the advantages thereof are best understood by referring to FIGS. 1-3 of the drawings, like numerals being used for like and corresponding parts of the various drawings.

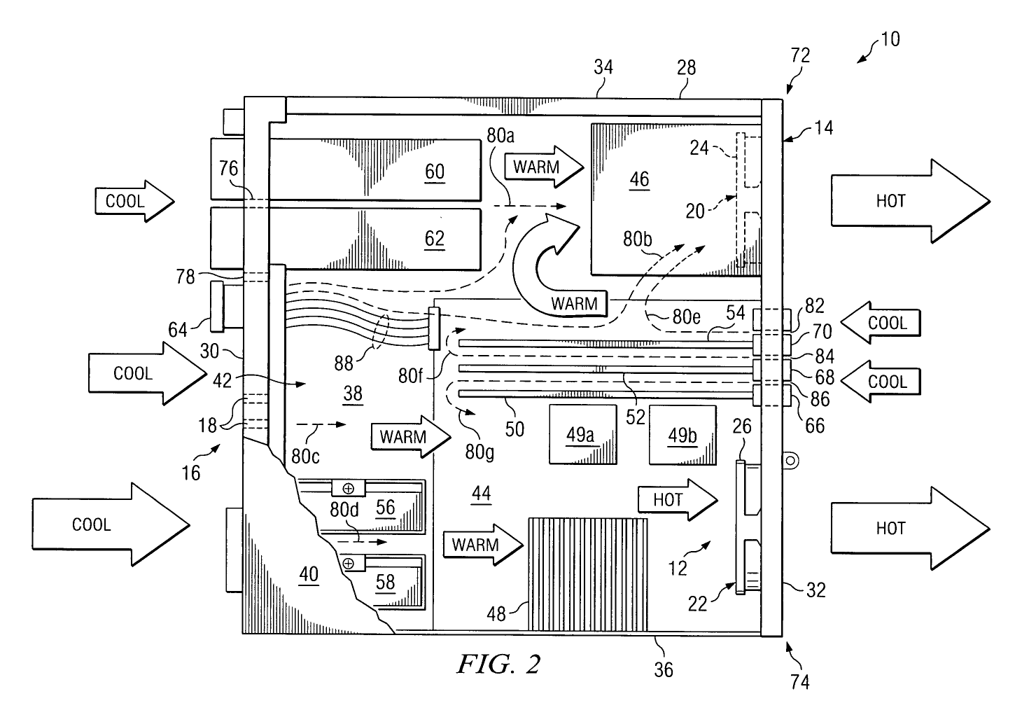

FIG. 1 is a diagram illustrating a computer system 10 in which an embodiment of a cooling system 12 is employed to advantage, and FIG. 2 is a side view of cooling system 12 of FIG. 1. In the embodiment illustrated in FIGS. 1 and 2, computer system 10 comprises a desktop computer system 14; however, it should be understood that computer system 10 may comprise any type of electronic computer system such as, but not limited to, a mini-tower computer system, an overhead projector, a cable set top box or any other type of computing/electronic system.

In the embodiment illustrated in FIGS. 1 and 2, computer system 14 comprises a chassis 28 comprising a front wall 30, a rear wall 32, a top wall 34, a bottom wall 36 and a pair of sidewalls 38 and 40. In the embodiment illustrated in FIGS. 1 and 2, chassis 28 supports and otherwise houses electronic operational components 42 for use in and/or otherwise forming computer system 14. In some embodiments, operational components 42 comprise a power supply 46; a motherboard 44 comprising a central processing unit (CPU) assembly 48 and a pair of chips 49a and 49b; a graphic card 50; a video card 52; and a sound card 54. Operational components 42 further comprise hard disk drives 56 and 58, optical disk drives 60 and 62, and an input/output module 64 to enable connection of external devices to computer system 14 such as, but not limited to, a printer, mouse, scanner, and/or a router. However, it should be understood that other and/or additional operational components 42 may be disposed in and/or otherwise form part of computer system 14.

In the embodiment illustrated in FIGS. 1 and 2, motherboard 44 is oriented adjacent to and parallel with sidewall 38 such that CPU assembly 48 is positioned near or adjacent to bottom wall 36. In the embodiment illustrated in FIGS. 1 and 2, bottom wall 36 is perpendicular to and extends between walls 30 and 32 of chassis 28. It should be understood that motherboard 44 may be otherwise positioned such as for example, positioning motherboard 44 adjacent to and parallel with sidewall 40 such that CPU assembly 48 is positioned near or adjacent to wall 34.

In the embodiment illustrated in FIGS. 1 and 2, cards 50, 52 and 54 are positioned adjacent rear wall 32 (in an orientation parallel to top wall 34 and bottom wall 36 and perpendicular to motherboard 44) and engage corresponding connector ports 66, 68 and 70 for cards 50, 52 and 54, respectively, extending through rear wall 32. Cards 50, 52 and 54 are disposed at an intermediate location within chassis 28 and at least partially between a pair of air circulation devices 20 and 22 to effectively separate air circulation devices 20 and 22 (e.g., at least a portion of one or more cards 50, 52, 54 disposed directly between air circulation devices 20 and 22). For example, motherboard 44 is oriented to position card 52 such that air circulation device 20 is disposed on one side of card 52 and air circulation device 22 is disposed on an opposite side of the card 52, thus enabling airflow across both sides of card 52. It should be understood that cards 50, 52 and/or 54 need not be disposed directly or physically between air circulation devices 20 and 22 while remaining at an intermediate location in chassis 28 such that air flows are generated across opposite sides of cards 50, 52 and/or 54. It should be understood that each card 50, 52 and/or 54 may be construed to have six sides (e.g., on opposite sides of a width, length, or thickness of a particular card) such that opposite sides of one of cards 50, 52 and/or 54 shall include opposite sides as measured across any of a width, length or thickness of such card 50, 52 and/or 54. In the embodiment illustrated in FIG. 1, hard disk drives 56 and 58 are positioned adjacent to a least one airflow inlet 16 and in a generally horizontal orientation (e.g., parallel to top wall 34 and bottom wall 36) to enable air to flow around and between hard disk drives 56 and 58. However, it should be understood that hard disk drives 56 and 58 may be otherwise oriented (e.g., vertically oriented so as to be parallel to sidewalls 38 and 40).

In the embodiment illustrated in FIGS. 1 and 2, cooling system 12 comprises airflow inlet 16 and air circulation devices 20 and 22 for drawing cooling air through computer system 14 to dissipate thermal energy generated therein. In the embodiment illustrated in FIG. 1, air circulation device 20 comprises a power supply fan 24 and air circulation device 22 comprises a system cooling fan 26. It should be understood that additional air inlets and air circulation devices may be used for increased thermal energy dissipation from computer system 14. For example, in the embodiment illustrated in FIG. 2, chassis 28 comprises an inlet 76 disposed between optical drives 60 and 62, an inlet 78 formed between input/output module 64, and inlets 82, 84 and 86, disposed on rear wall 32. In some embodiments, additional inlets may be provided on sidewalls 38 and/or 40.

In the embodiment illustrated in FIGS. 1 and 2, fans 24 and 26 are positioned on or adjacent to rear wall 32 and disposed generally within corners 72 and 74 (e.g., at or near the intersection of rear wall 32 with top wall 34 and bottom wall 36, respectively) of chassis 28 to draw cooling air through chassis 28 via airflow inlets 16, 76, 78, 82, 84 and/or 86. According to some embodiments, fans 24 and 26 are spaced apart such that one or more operational components 42, such as, but not limited to, graphic card 50, video card 52 and sound card 54, are disposed at least partially between fans 24 and 26, thereby creating separate airflow streams on each or opposite sides of at least one of cards 50, 52 and 54 (e.g., in FIGS. 1 and 2, the airflow streams are at least on opposite sides of at least one of cards 50, 52 and 54 as measured across a thickness of cards 50, 52 and 54). It should be understood that fans 24 and 26 may be otherwise located (e.g., on or adjacent to front wall 30, sidewalls 38 and 40, or fans 24 and 26 may be switched such that fan 24 is adjacent to corner 74 and fan 26 is adjacent to corner 72). In operation, fans 24 and 26 draw ambient air into chassis 28 through inlets 16, 76, 78, 82, 84 and/or 86. As air moves through chassis 28 and across operational components 42, thermal energy generated by operational components 42 is removed from chassis 28.

In FIG. 2 airflow paths 80a-80g through chassis 28 of computer system 14 are illustrated. In the embodiment illustrated in FIG. 2, computer system 14 comprises airflow inlets 16, 76 and 78 on front wall 30, and airflow inlets 82, 84 and 86 on rear wall 32. In operation, fans 24 and 26 draw ambient air inside chassis 28 through inlets 16, 76, 78, 82, 84 and 86 toward fans 24 and 26, as illustrated by airflow paths 80a-80g. As the air flows along paths 80a-80f, thermal energy generated by components 42, such as disk drives 60 and 62, hard drives 56 and 58, graphic card 50, and chips 49a and 49b, for example, is dissipated by the cooling air flowing around each of the operational components 42. For example, in the embodiment illustrated in FIG. 2, airflow path 80a flows through opening 76 and between optical devices 60 and 62 toward power supply fan 24. As air travels between optical devices 60 and 62, any thermal energy buildup between the devices is pulled toward power supply fan 24 where it exits chassis 28. Similarly, airflow path 80b is drawn through opening 78 by power supply fan 24. Airflow path 80b extends along the underside of optical drive 62 and across at least a portion of card 54 through power supply fan 24. Thus, cooling air traveling along airflow path 80b transports excess heat generated by operational components 42, such as, but not limited to, optical device 62 and cards 50, 52 and 54 through power supply fan 24. Airflow paths 80c and 80d illustrate cooling air flow through openings 16 flowing across and between hard disk drives 56 and 58. Airflow paths 80c and 80d continue across motherboard 44 and CPU 48 toward system fan 26, as illustrated in FIG. 2. In the embodiment illustrated in FIG. 2, airflow paths 80e, 80f and 80g enter chassis 28 through openings 82 84 and 86 respectively. In the embodiment illustrated in FIG. 2, airflow path 80e transports cooling airflow over the top surface of card 54 to remove excess heat generated thereby. As cooling airflow travels over card 54, the warmed cooling air is drawn trough an opening 23 on the bottom side of power supply fan 24 to exit from chassis 28 through power supply fan 24. Cooling airflow path 80f flows between cards 52 and 54 along the length of cards 52 and 54 and is removed from chassis 28 by fan 24, as illustrated in FIG. 2. Likewise, cooling airflow path 80g flows between cards 50 and 52 to remove thermal energy and directs the thermal energy through system fan 26 to remove the warmed cooling air from chassis 28. In the embodiment illustrated in FIG. 2, fan 24 creates at least airflow path 80a through chassis 28 and fan 22 creates at least airflow path 80d through chassis 28.

According to some embodiments, by placing fans 26 and 28 at or near corners 72 and 74, respectively, and further, by orienting motherboard 44 such that CPU 48 is disposed adjacent bottom wall 36 of chassis 28 and cards 50, 52 and 54 are disposed at least partially between fans 24 and 26 and/or at an intermediate location within chassis 28 as illustrated in FIGS. 1 and 2, cooling air is more evenly distributed inside chassis 28. This configuration enables a distributed and front wall-to-back-wall airflow (e.g., substantially parallel airflow paths between top and bottom walls 34 and 36 traveling in the direction between front wall 30 and rear wall 32) to effectively dissipate heat and reduce and/or eliminate any stagnant areas within chassis 28. Thus, both system fan 22 and power supply fan 24 dissipate heat from heat generating operational components 42, such as for example, graphics card 54. Furthermore, the present orientation of motherboard 44 enables a connector member 90 on motherboard 44 to be disposed in general proximity to input/output module 64 such that a plurality of cables 88 can communicatively couple input/output module 64 with motherboard 44. Thus, minimal lengths of connecting cables can be used.

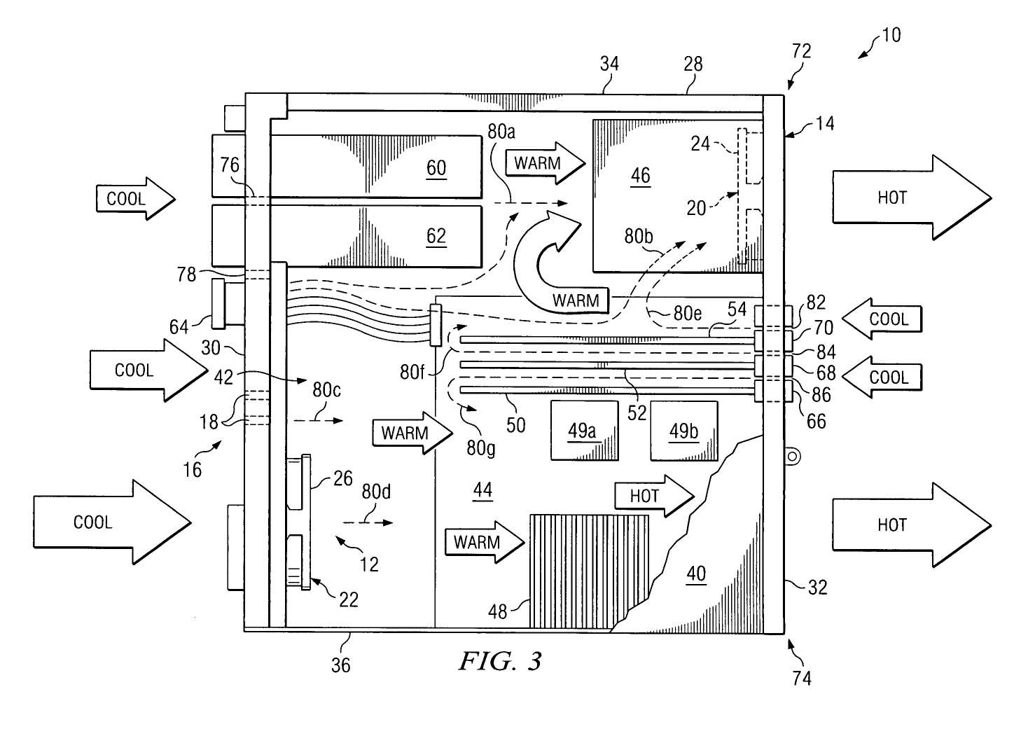

FIG. 3 is a diagram illustrating another embodiment of cooling system 12. In the embodiment illustrated in FIG. 3, air circulation device 22 is disposed near and/or on front wall 30 of chassis 28 instead of on rear wall 32 of chassis 28 (e.g., as illustrated in FIGS. 1 and 2). Thus, in the embodiment illustrated in FIG. 3, air circulation devices 20 and 22 are disposed on different walls of chassis 28 each creating and/or otherwise producing an airflow path through chassis 28. Thus, as illustrated in FIG. 3, air circulation devices 20 and 22 generate and/or otherwise produce at least two different airflow paths or streams through chassis 28. Further, as illustrated in FIG. 3, the airflow paths produced by respective air circulation devices 20 and 22 extend past at least two opposite sides of one or more cards 50, 52 and 54.

Thus, embodiments enable distributed airflow paths 80a-80f through chassis 28 and over operational components 42 to dissipate thermal energy while also reducing the amount of wiring/cabling between operational components 42.

What is claimed is:

1. A computer system cooling system, comprising:
a chassis comprising a first air circulation device and a second air circulation device and a motherboard disposed therein, the motherboard oriented to position a card coupled thereto such that the first air circulation device is disposed on one side of the card and the second air circulation device is disposed on an opposite side of the card.

2. The cooling system of claim 1, wherein the motherboard is oriented to position the card at least partially between the first and second air circulation devices.

3. The cooling system of claim 1, wherein at least one of the first and second air circulation devices comprises a system fan.

4. The cooling system of claim 1, wherein at least one of the first and second air circulation devices comprises a power supply fan.

5. The cooling system of claim 1, wherein the first and second air circulation devices are oriented to generate parallel airflow paths across the motherboard.

6. The cooling system of claim 1, wherein the first air circulation device is disposed within a corner of the chassis.

7. The cooling system of claim 6, wherein the second air circulation device is disposed within another corner of the chassis.

8. The cooling system of claim 1, wherein the motherboard is oriented to position the card at an intermediate location within the chassis.

9. The system of claim 1, wherein the first air circulation device produces a first airflow path past the one side of the card and the second air circulation device produces a second airflow path past the another side of the card.

10. A method of manufacturing a computer system cooling system, comprising:
disposing a first air circulation device, a second air circulation device and a motherboard within a chassis; and
orienting the motherboard to position a card coupled thereto such that the first air circulation device is disposed on one side of the card and the second air circulation device is disposed on an opposite side of the card.

11. The method of claim 10, further comprising orienting the motherboard to position the card at least partially between the first and second air circulation devices.

12. The method of claim 10, further comprising providing a system fan for least one of the first and second air circulation devices.

13. The method of claim 10, further comprising providing a power supply fan for at least one of the first and second air circulation devices.

14. The method of claim 10, further comprising orienting the first and second air circulation devices to generate parallel airflow paths across the motherboard.

15. The method of claim 10, further comprising disposing first air circulation device within a corner of the chassis.

16. The method of claim 15, further comprising disposing the second air circulation device within another corner of the chassis.

17. The method of claim 10, further comprising orienting the motherboard to position the card at an intermediate location of the chassis.

18. A computer system cooling system, comprising:
a means for supporting a first and second means for circulating cooling air and a motherboard means, the motherboard means oriented to position a card such that the first circulating means is disposed on one side of the card and the second circulating means is disposed on an opposite side of the card.

19. The cooling system of claim 18, wherein the motherboard means is oriented to position the card at least partially between the first and second circulating means.

20. The cooling system of claim 18, wherein the first air circulation means is disposed within a corner of the supporting means.

21. The cooling system of claim 20, wherein the second circulating means is disposed within another corner of the supporting means.

22. A computer system cooling system, comprising:
a chassis comprising a first air circulation device and a second air circulation device for generating at least two airflow paths through the chassis, the first and second air circulation devices each disposed on a different wall of the chassis.

23. The system of claim 22, wherein the first and second air circulation devices are each disposed in a corner of the chassis.

24. The system of claim 22, wherein one of the at least two airflow paths extends past one side of a card disposed within the chassis and another of the at least two airflow paths extends past another side of the card.

25. The system of claim 22, wherein one of the at least two airflow paths extends past one side of a card disposed within the chassis and another of the at least two airflow paths extends past an opposite side of the card.
